(19) United States
(12) Patent Application Publication
(10) Pub. No.: US 2004/0000672 A1
(43) Pub. Date: Jan. 1, 2004

(54) High-power light-emitting diode structures

(75) Inventors: John C.C. Fan, Brookline, MA (US); Hong K. Choi, Sharon, MA (US); Steve Tchang-hun Oh, Sharon, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kopin Corporation, Taunton, MA

(21) Appl. No.: 10/187,466

(22) Filed: Jun. 28, 2002

(51) Int. Cl. H01L 27/15; H01L 31/12; H01L 33/00

(52) U.S. Cl. 257/79

(57) ABSTRACT

High-efficiency light-emitting diode structures are disclosed which reduce the current flow directly underneath the thick p-bonding pad. The devices can further include a light-reflecting layer at the back of the substrate.

### INCORPORATION BY REFERENCE

The entire teachings of the following applications are incorporated herein by reference: U.S. Provisional Application entitled LIGHT-EMITTING DIODE DEVICE GEOMETRY, by John C. C. Fan, Hong K. Choi, Steven Oh, J. C. Chen, and Jagdish Narayan, (Attorney Docket No. 0717.2032-000), filed on Jun. 17, 2002; United States Patent Application entitled ELECTRODE FOR P-TYPE GALLIUM NITRIDE-BASED SEMICONDUCTORS, by Hong K. Choi, Bor-Yeu Tsaur, John C. C. Fan, Shirong Liao, and Jagdish Narayan, (Attorney Docket No. 0717.2030-000), filed on even date herewith; U.S. patent application entitled BONDING PAD FOR GALLIUM NITRIDE-BASED LIGHT-EMITTING DEVICE, by Hong K. Choi, Bor-Yeu Tsaur, and John C. C. Fan, (Attorney Docket No. 0717.2031-000), filed on even date herewith, and U.S. Provisional Application entitled DOMAIN EPITAXY FOR THIN FILM GROWTH, by Jagdish Narayan, (Attorney Docket No. 0717.2033-000), filed on even date herewith.

### BACKGROUND OF THE INVENTION

Recently, much attention has been focused on III-V nitride-based semiconductors, and particularly GaN-based semiconductors, for blue, green and ultraviolet light emitting diode (LED) applications. One important reason is that GaN-based LEDs have been found to exhibit excellent light emission at room temperature.

In a typical example of a GaN-based semiconductor LED, a layer of an n-type semiconductor material and a layer of a p-type semiconductor material are sequentially stacked on a suitable substrate, such as a sapphire substrate. In certain embodiments, an active region (which can be a single or multiple quantum well structure, for example) is disposed between the p-type and n-type semiconductor layers. In general, the n-type semiconductor layer is formed over the substrate layer, and the p-type semiconductor layer is formed above the n-type layer.

Because the substrate is normally comprised of an electrically insulating material, such as sapphire, the electrical contacts to the device are typically made on the top side of the device, opposite to the substrate layer. A portion of the top side of the device is typically etched to expose a region of the n-type semiconductor layer, and an n-electrode of a suitable metallic material is deposited on the exposed region of the n-type semiconductor layer.

The p-type GaN-based semiconductor layer is normally much more resistive than the n-type layer. Consequently, the p-electrode is usually made to cover substantially the entire surface of the p-type semiconductor layer in order to assure the uniform application of current to the entire p-type semiconductor layer, and thus obtain uniform light emission from the device. The p-electrode typically comprises one or more layers of a metallic material deposited over substantially the entire surface of the p-type semiconductor layer. The p-electrode layers are generally annealed at a suitably high-temperature to render the electrode layer light-transmissive. The p-electrode layer is preferably made very thin to increase light transmission from the top surface of the device.

A bonding pad of a suitable metallic material is then deposited over a region of the light-transmissive p-electrode.

The substrate is lapped and polished to a thickness of less than 100 μm to facilitate scribing and breaking of the wafer into individual chips. The LED chip is then mounted on a suitable support, such as a metal surface, using an epoxy. Electrical interconnects are bonded to the n-electrode and the p-bonding pad to produce a current across the light-emitting semiconductor layers.

### SUMMARY OF THE INVENTION

The present invention relates to improvements in the design of semiconductor LEDs to provide enhanced efficiency in the light output of the device. In the example of the III-V nitride-based semiconductor described above, for instance, the thin p-electrode layer helps spread the current uniformly throughout the semiconductor material layers, and thus promotes uniform light emission from the device. However, the thicker bonding pad above the p-electrode is generally not light transmissive, and partially absorbs some of the light generated in the device. Consequently, light generated directly below this bonding pad cannot escape the structure efficiently.

Also, the reflection from the bottom surface of the substrate is generally not very high. Typically, the finished LED chips are mounted on a metal support surface with an epoxy. However, the reflectivity of the epoxy is not very high, and can vary greatly from chip to chip.

Accordingly, in one aspect the present invention comprises a semiconductor LED device comprising a substrate, and a semiconductor device structure over the substrate, the device structure comprising an n-type semiconductor layer, and a p-type semiconductor layer over the n-type semiconductor layer. The semiconductor device structure can also include an active region (such as a single quantum well or multiple quantum well structure) located between the n-type and p-type semiconductor layers. The LED additionally comprises a first electrode in contact with the n-type semiconductor layer, a light-transmissive p-electrode layer substantially covering the p-type semiconductor layer, and a bonding pad in electrical contact with the light-transmissive p-electrode layer. The LED also comprises an insulating region having a first and second major surface, where the first major surface of the insulating region contacts the underside of the bonding pad, and the second major surface contacts the surface of the p-type semiconductor layer.

Because the insulating region is located directly under the bonding pad, current is not spread uniformly throughout the device by the p-electrode. Instead, less current flows in the region directly under the bonding pad, and more current is available to flow in the rest of the device. Consequently, less light is generated under the non-transmissive, light-absorbing bonding pad, and more light can be generated elsewhere in the device. The net light emission of the device is thereby improved.

In an alternative embodiment, a portion of the light-transmissive p-electode layer can be removed, and a portion of the p-bonding pad can be made to directly contact the p-type semiconductor layer. Since the p-bonding pad does not form a good ohmic contact with the p-type semiconductor layer, less current flows directly under the bonding pad area. Accordingly, less light is generated under the non-transmissive, light-absorbing bonding pad, and more light can be generated elsewhere in the device.

In another aspect, the present invention comprises a semiconductor LED comprising a substrate having a first and second major surface, and a semiconductor device structure over the first major surface of the substrate, the device structure including an n-type semiconductor layer, and a p-type layer over the n-type semiconductor layer. The device further includes a first electrode in electrical contact with the n-type semiconductor layer, a second electrode in contact with the p-type semiconductor layer, and a bonding pad in contact with the second electrode. In addition, a reflector layer contacts the second major surface of the substrate, opposite the semiconductor device structure.

In certain embodiments, the reflector layer is a metallic material, such as aluminum, which can be evaporated (deposited) on the backside surface of the substrate. The reflective layer generally provides higher and more reproducible reflectivity from the underside of the substrate relative to an epoxy adhesive layer. The overall efficiency of the LED is thus improved.

### BRIEF DESCRIPTION OF THE DRAWINGS

FIG. 1 is a cross-sectional view schematically illustrating a conventional semiconductor light emitting diode structure;

FIG. 2 is a cross-sectional view schematically illustrating a semiconductor light emitting diode according to the present invention; and

FIG. 3 is a cross-sectional view schematically illustrating a second semiconductor light emitting diode according to the present invention.

### DETAILED DESCRIPTION OF THE INVENTION

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

The present invention relates in general to improved efficiency semiconductor devices, and in particular to improved efficiency semiconductor light emitting diodes (LEDs). In particular embodiments, the LEDs of the present invention include at least one layer of a GaN-based semiconductor material. As used herein, the term “GaN-based semiconductor material” includes a semiconductor material that can be represented by the formula InₓAl_{y}Ga_{1-x-y}N, where 0≦x≦1, 0≦y≦1, and x+y≦1.

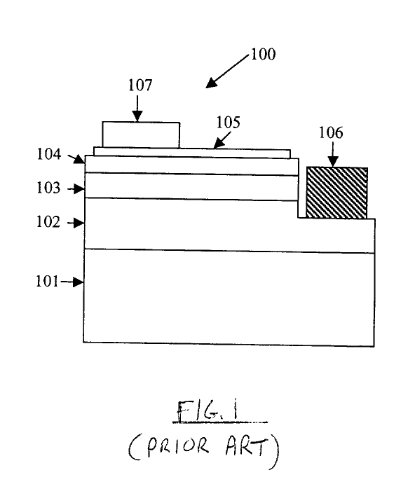

Turning now to FIG. 1, an example of a conventional GaN-based LED is shown in schematic cross-section. The LED device 100 includes a substrate 101, which in this example comprises a sapphire substrate. Directly above the substrate 101 is a layer of n-type GaN semiconductor material 102, typically between about 2 μm and 10 μm thick. The n-type semiconductor layer 102 is preferably doped with an n-type dopant, such as silicon (Si). An undoped GaN material exhibiting an n-type conductivity could also be used.

Above the n-type semiconductor layer 102 is an active region 103, followed by a layer of p-type semiconductor material 104, typically between about 0.1 μm and 2 μm thick. In general, an active region comprises a region of semiconductor material that has a band gap which is smaller than the band gap of the semiconductor layers on either side of the active region. The larger band gap n-type and p-type semiconductor materials create potential barriers on both sides of the active region and cause carriers (i.e., holes and electrons) to be confined in the active region, where they can combine to emit light.

As shown in FIG. 1, the active region comprises a single or multiple quantum well structure formed of a gallium nitride-based semiconductor material (such as In_{X}Ga_{1-X}N, for example) having a lower band-gap than the n-type and p-type gallium nitride-based semiconductor layers sandwiching it. An active region having a multiple quantum-well structure includes multiple well layers alternately stacked with multiple barrier layers (such as GaN, for example) that have a higher band-gap than the well layers. The outer most layers of the active region are well layers and have lower band-gaps than the n-type and p-type gallium nitride-based semiconductor layers sandwiching the active region. Typically, the thickness of a well layer in a quantum-well structure is about 70 Å or less, and the barrier layers are about 150 Å or less. Generally, the well layers and barrier layers in a quantum-well structure are undoped.

Above the active region 103 is a p-type semiconductor layer 104 of GaN. In general, a p-type gallium nitride-based semiconductor material is a gallium nitride-based semiconductor material that includes a p-type dopant. The p-type dopants (also called an acceptor) for gallium nitride-based semiconductor materials include Group II elements such as cadmium, zinc, beryllium, magnesium, calcium, strontium, and barium. A preferred p-type dopant is magnesium. Typically, during growth of the gallium nitride-based semiconductor material gaseous compounds containing hydrogen atoms are thermally decomposed to form the semiconductor material. The released hydrogen atoms, which are present mainly as protons, become trapped in the growing semiconductor material, and combine with p-type dopant inhibiting their acceptor function. To improve the conductivity of a p-type gallium nitride-based semiconductor material, the material may be placed in a high electric field, typically above 10,000 volts/cm for about 10 minutes or more. The protons trapped in the semiconductor material are drawn out of the material to the negative electrode, thereby activating the function of the p-type dopants (see U.S. patent application Ser. No. 10/127,345, the entire teachings of which are incorporated herein by reference). Alternatively, the conductivity of the p-type gallium nitride-based semiconductor material can be improved by annealing the material at a temperature above 600° C. in a nitrogen environment for 10 minutes or more (see U.S. Pat. No. 5,306,662, the entire teachings of which are incorporated herein by reference).

Directly above the p-type semiconductor layer 104 is a p-electrode layer 105. In general, the p-type electrode layer is formed of a metallic material of one or more metals (such as gold, nickel, platinum, aluminum, tin, indium, chromium, and titanium). The metallic material is deposited over substantially the entire top surface of the p-type semiconductor layer, and is annealed at a high-temperature (e.g. >450° C.). The p-electrode layer 105 is preferably light transmissive, meaning that it is able to transmit at least 1% of the light emitted from the gallium nitride-based semiconductor device therethrough, and typically transmits about 50% to about 70% or more of the light emitted from the gallium nitride-based semiconductor device.

The p-electrode layer 105 preferably forms an ohmic contact with the p-type semiconductor layer over an area where two materials are in contact, such that the current flowing through the interface between the two layers is approximately proportional to the potential difference between the layers.

The LED of FIG. 1 additionally includes an n-electrode 106 and a p-bonding pad 107 for providing electrical contact to the device. The n-electrode is formed of a metallic material of one or more metals (such as gold, titanium, aluminum, indium, platinum, and palladium) deposited on an exposed surface of the n-type semiconductor layer 102. The exposed surface of the n-type layer is generally produced by etching the upper layers of the device to expose a region of the n-type semiconductor layer.

The p-bonding pad 107 is formed of a metallic material of one or more metals (such as gold, titanium, aluminum, indium, platinum, and palladium) deposited on the p-electrode layer 105.

In the device illustrated in FIG. 1, the p-type GaN-based semiconductor layer 104 possesses only moderate conductivity relative to the n-type semiconductor layer 103. Accordingly, the p-electrode layer 105 is typically formed to cover substantially the entire surface of the p-type semiconductor layer 104 in order to ensure uniform application of current to the entire layer and obtaining uniform light emission from the LED. However, this geometry requires that the p-electrode be light-transmissive so that light emitted by the LED can be observed through the p-electrode. Typically, the p-electrode layer must be very thin (about 0.01 μm) in order to be light transmissive and thus it is difficult to attach a bonding wire directly to it. Therefore, a bonding pad 107 is used to attach the bonding wire to the p-electrode.

Because the bonding pad 107 is in direct contact with the p-electrode layer 105, the bonding pad typically covers a portion of the light-emitting surface of the LED. The bonding pad is generally much thicker than the thin p-electrode layer, and therefore transmits significantly less light than the p-electrode. Consequently, the bonding pad interferes with the transmission of at least some of the light generated in the regions underlying the pad.

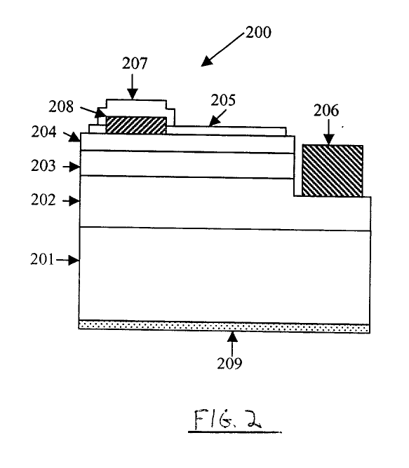

Turning now to FIG. 2, an LED in accordance with one aspect of the present invention is shown in schematic cross-section. As in the device of FIG. 1, the LED device 200 of FIG. 2 includes a substrate 201, and a layer of n-type GaN-based semiconductor material 202 above the substrate. Above the n-type semiconductor layer 202 is an active region 203, which in this embodiment comprises a multiple quantum well structure of alternately stacked In_{X}Ga_{1-X}N/GaN layers. Above the active region 203 is a layer of a p-type GaN-based semiconductor material 204.

It will be understood that in addition to a multiple quantum well structure, the active region 203 could also comprise a single quantum well structure. Also, in other embodiments, the active region could be eliminated entirely, and the n-type and p-type semiconductor layers 202, 204 can be made in direct contact with each other.

Above the p-type semiconductor layer 204 is a p-electrode layer 205 of one or more metallic materials. As in the device of FIG. 1, the p-electrode layer is preferably light transmissive, and forms an ohmic contact with the p-type semiconductor layer.

Also as in the device of FIG. 1, an n-electrode 206 forms an electrical contact with an exposed region of the n-type semiconductor layer 202. Also, a bonding pad 207 forms an electrical contact with the p-electrode 205.

As illustrated in FIG. 2, the LED also includes an insulating region 208 between the surface of the p-type semiconductor layer 204 and the underside of the bonding pad 207. The insulating material, such as SiO₂ or Si₃N₄, is deposited by plasma-enhanced chemical vapor deposition or sputtering, and it can be patterned using photolithography and wet chemical etching. The p-electrode layer 205 and the bonding pad 207 are then formed. The insulating region 208 reduces current flow in the region directly under the bonding pad 207, and more current is available to flow in the rest of the device. Consequently, less light is generated under the non-transmissive, light-absorbing bond pad 207, and more light can be generated elsewhere in the device.

Also shown in FIG. 2 is reflector layer 209. In general, the reflector layer directly contacts the bottom surface of the substrate 201 opposite the semiconductor layers. The reflector layer 209 preferably comprises one or more metallic materials with high reflectivitiy, such as aluminum, silver, and/or gold, and is evaporated directly onto the surface of the substrate 201. To facilitate breaking of the wafer into small chips, typically the substrate is thinned prior to deposition of the reflector layer, using such methods as lapping and polishing. The substrate is preferably thinned to a thickness of less than about 100 μm.

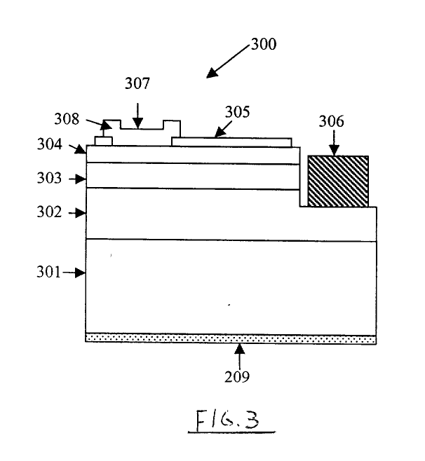

An alternative embodiment is shown in FIG. 3. As in the device of FIG. 2, the LED device 300 of FIG. 3 includes a substrate 30, and a layer of n-type GaN-based semiconductor material 302 above the substrate. Above the n-type semiconductor layer 302 is an active region 303, which in this embodiment comprises a multiple quantum well structure of alternately stacked In_{X}Ga_{1-X}N/GaN. Above the active region 303 is a layer of p-type GaN-based semiconductor material 304.

Above the p-type semiconductor layer 304 is a light-transmissive p-electrode layer 305 of one or more metallic materials which forms an ohmic contact with the p-type semiconductor layer 302. An n-electrode forms an electrical contact with an exposed region of the n-type semiconductor layer 302. Also, a bonding pad 307 forms an electrical contact with the p-electrode layer 305. A reflector layer 307 is located on the back side of the substrate 301, opposite the semiconductor device layers.

As shown in FIG. 3, the p-electrode layer 305 does not completely extend over the p-type semiconductor layer 304, leaving a small region of the p-type semiconductor layer exposed. The bonding pad 307 is deposited partially over the p-type electrode layer 305, and partially over the exposed region of the p-type semiconductor layer 304, so that a portion of the bonding pad 307 directly contacts the p-type semiconductor layer 304. In general, the bonding pad 307 forms an ohmic contact with the p-electrode layer 305, but does not form a good ohmic contact with the p-type semiconductor layer 304. Because there is substantially no ohmic contact between the bonding pad 307 and the p-type semiconductor layer 304, the bonding pad acts like an insulator at this interface. The effect is similar to having an insulating layer under the bonding pad, such as in FIG. 2. There is less current flow in the region directly under the bonding pad 307, and more current is available to flow in the rest of the device. Consequently, less light is generated under the non-transmissive, light-absorbing bond pad, and more light can be generated elsewhere in the device.

While this invention has been particularly shown and described with references to preferred embodiments thereof, it will be understood by those skilled in the art that various changes in form and details may be made therein without departing from the scope of the invention encompassed by the appended claims.

What is claimed is:

1. A semiconductor device comprising:
a substrate having a first and second major surface;
a semiconductor device structure over the first major surface of the substrate, the device structure comprising an n-type semiconductor layer, and a p-type semiconductor layer over the n-type semiconductor layer;
an electrode in electrical contact with the n-type semiconductor layer; and
a light-transmissive electrode layer substantially covering the p-type semiconductor layer;
a bonding pad in electrical contact with the light-transmissive electrode layer; and
an insulating region having a first and second major surface, the first major surface contacting the bonding pad and the second major surface contacting the p-type semiconductor layer; and
a reflector layer contacting the second major surface of the substrate.

2. The semiconductor device of claim 1, additionally comprising an active region between the n-type semiconductor layer and the p-type semiconductor layer.

3. The semiconductor device of claim 2, wherein the active layer comprises a single or multiple quantum well structure.

4. The semiconductor device of claim 1, wherein at least one of the p-type semiconductor layer and the n-type semiconductor layer comprises a GaN-based semiconductor material.

5. The semiconductor device of claim 1, wherein the reflector layer comprises one or more metallic materials.

6. The semiconductor device of claim 5, wherein the one or more metallic materials comprise at least one of aluminum, gold, and silver.

7. A method for producing a semiconductor device comprising:
providing a substrate having a first and second major surface;
providing a semiconductor device structure over the first major surface of the substrate, the device structure comprising an n-type semiconductor layer, and a p-type semiconductor layer over the n-type semiconductor layer;
providing an electrode in electrical contact with the n-type semiconductor layer;
providing a light-transmissive electrode layer substantially covering the p-type semiconductor layer;
providing a bonding pad in electrical contact with the light-transmissive electrode layer;
providing an insulating region having a first and second major surface, the first major surface contacting the bonding pad and the second major surface contacting the p-type semiconductor layer; and
providing a reflector layer contacting the second major surface of the substrate.

8. The method of claim 7, wherein the step of providing a reflector layer comprises evaporating one or more metallic materials on the second major surface of the substrate.

9. The method of claim 8, wherein the one or more metallic materials comprises at least one of aluminum, gold, and silver.

10. A semiconductor device comprising:
a substrate having a first and second major surface;
a semiconductor device structure over the first major surface of the substrate, the device structure comprising an n-type semiconductor layer, and a p-type semiconductor layer over the n-type semiconductor layer;
a first electrode in electrical contact with the n-type semiconductor layer;
a light-transmisive electrode layer substantially covering the p-type semiconductor layer to define an exposed region of the p-type semiconductor layer;
a substantially non-transmissive light-absorbing bonding pad disposed partially over the light-transmissive electrode layer, and partially over the exposed region of the p-type semiconductor layer, the bonding pad forming an ohmic contact with the light-transmissive electrode layer, and forming substantially no ohmic contact with the p-type semiconductor layer; and
a reflector layer contacting the second major surface of the substrate.

11. The semiconductor device of claim 10, additionally comprising an active region between the n-type semiconductor layer and the p-type semiconductor layer.

12. The semiconductor device of claim 11, wherein the active layer comprises a single or multiple quantum well structure.

13. The semiconductor device of claim 10, wherein at least one of the p-type semiconductor layer and the n-type semiconductor layer comprises a GaN-based semiconductor material.

14. The semiconductor device of claim 10, wherein the reflector layer comprises one or more metallic materials.

15. The semiconductor device of claim 14, wherein the one or more metallic materials comprise at least one of aluminum, gold, and silver.

16. A method for producing a semiconductor device comprising:
providing a substrate having a first and second major surface;
providing a semiconductor device structure over the first major surface of the substrate, the device structure comprising an n-type semiconductor layer, and a p-type semiconductor layer over the n-type semiconductor layer;
providing a first electrode in electrical contact with the n-type semiconductor layer;
providing a light-transmisive electrode layer substantially covering the p-type semiconductor layer to define an exposed region of the p-type semiconductor layer;
providing a substantially non-transmissive light-absorbing bonding pad disposed partially over the light-transmissive electrode layer, and partially over the exposed region of the p-type semiconductor layer, the bonding pad forming an ohmic contact with the light-transmissive electrode layer, and forming substantially no ohmic contact with the p-type semiconductor layer; and
providing a reflector layer contacting the second major surface of the substrate.

17. The method of claim 16, wherein the step of providing a reflector layer comprises evaporating one or more metallic materials on the second major surface of the substrate.

18. The method of claim 17, wherein the one or more metallic materials comprises at least one of aluminum, gold, and silver.
